(19) United States
(12) Patent Application Publication
(10) Pub. No.: US 2023/0011276 A1
(43) Pub. Date: Jan. 12, 2023

(54) MEMORY DEVICE FOR TERNARY COMPUTING

(71) Applicant: SONIC STAR GLOBAL LIMITED, Road Town (VG)

(72) Inventors: Chih-Chieh CHIU, Hsinchu (TW); Chun-Yen LIN, Ji'an Township (TW); Chih-Lung CHEN, Zhubei (TW)

(21) Appl. No.: 17/562,568

(22) Filed: Dec. 27, 2021

Related U.S. Application Data
(60) Provisional application No. 63/220,223, filed on Jul. 9, 2021.

(51) Int. Cl. G11C 7/16; G11C 7/10; G11C 8/08

(52) U.S. Cl. CPC G11C 7/16; G11C 7/1048; G11C 7/1063; G11C 7/109; G11C 8/08

(57) ABSTRACT

A memory device includes a pair of memory cells, an analog-to-digital converter (ADC), and a processing circuit. The pair of memory cells has a first memory cell and a second memory cell. The ADC, having a first input terminal and a second input terminal, is configured to convert a first data signal at the first input terminal and a second data signal at the second input terminal into a digital output indicating a data value associated with a particular state stored in the pair of memory cells. The processing circuit, coupled to a storage node of the first memory cell, a storage node of the second memory cell, and the first and the second input terminals, is configured to selectively adjust the first data signal and the second data signal according to first data stored in the first memory cell and second data stored in the second memory cell.

### PRIORITY CLAIM AND CROSS-REFERENCE

The present application claims priority to U.S. Provisional Patent Application No. 63/220,223, filed on Jul. 9, 2021, the entire disclosure of which is incorporated herein by reference.

### BACKGROUND

The present disclosure relates to memory devices and, more particularly, to a memory device for ternary computing.

Deep learning utilizes artificial neural networks for training machines to simulate the behavior of the human brain. The trained machines can learn from large amounts of data, classify images and recognize speech as the human brain does. A convolutional neural network (CNN) is a type of artificial neural network which can be successfully applied to recommender systems, computer vision tasks, image/object recognition, and natural language processing. One of the main advantages of the CNN is that it can automatically detect important features without any human supervision. Also, the CNN can achieve high accuracy and computationally efficiency. The CNN can run on an in-memory computing system to efficiently perform arithmetic operations based on bitline computing, thereby reducing energy-costly data transfers. These advantages make the CNN universally attractive.

There are a host of hardware accelerators for various machine-learning models. Ternary memory storage is becoming increasingly popular thanks to the recent algorithmic advances in artificial neural network. Ternary memory-based systems are being extensively explored in CNN computations since they provide both lower memory requirement as well as improved accuracy for deep learning networks.

### SUMMARY

The described embodiments provide a memory device for ternary computing.

Some embodiments described herein may include a memory device. The memory device includes a pair of memory cells, an analog-to-digital converter (ADC), and a processing circuit. The pair of memory cells has a first memory cell and a second memory cell. The ADC has a first input terminal and a second input terminal. The ADC is configured to convert a first data signal at the first input terminal and a second data signal at the second input terminal into a digital output indicating a data value associated with a particular state stored in the pair of memory cells. The processing circuit is coupled to a storage node of the first memory cell, a storage node of the second memory cell, and the first and the second input terminals of the ADC. The processing circuit is configured to selectively adjust the first data signal and the second data signal according to first data stored on the storage node of the first memory cell and second data stored on the storage node of the second memory cell. The first data and the second data jointly represent a plurality of states stored in the pair of memory cells.

Some embodiments described herein may include a memory device. The memory device includes a pair of memory cells, a first switch, a second switch, a third switch, a fourth switch, and a signal generator circuit. The pair of memory cells has a first memory cell and a second memory cell. The first switch is controlled by first data stored on a storage node of the first memory cell to selectively couple a first connection terminal to a reference signal. The second switch is controlled by second data stored on a storage node of the second memory cell to selectively couple a second connection terminal to the reference signal. The third switch is selectively made conductive between the first connection terminal and a first data terminal. The fourth switch is selectively made conductive between the second connection terminal and a second data terminal. The signal generator circuit, coupled to the first data terminal and the second data terminal, is configured to generate an output signal according to a first data signal at the first data terminal and a second data signal at the second data terminal. The first data and the second data jointly represent a plurality of states stored in the pair of memory cells, and the output signal indicates a data value associated with a particular state stored in the pair of memory cells.

Some embodiments described herein may include a memory device. The memory device includes a pair of memory cells, a first switch, a second switch, a third switch, a fourth switch, and a signal generator circuit. The pair of memory cells has a first memory cell and a second memory cell. A storage node of the first memory cell is arranged for storing first data, and a storage node of the second memory cell is arranged for storing second data. The first switch is controlled by the first data to selectively couple a first connection terminal to a complementary storage node of the second memory cell. The complementary storage node of the second memory cell is arranged for storing a complement of the second data. The second switch is controlled by a complement of the first data to selectively couple a second connection terminal to the storage node of the second memory cell. The third switch is selectively made conductive between the first connection terminal and a first data terminal. The fourth switch is selectively made conductive between the second connection terminal and a second data terminal. The signal generator circuit, coupled to the first data terminal and the second data terminal, is configured to generate an output signal according to a first data signal at the first data terminal and a second data signal at the second data terminal. The first data and the second data jointly represent a plurality of states stored in the pair of memory cells, and the output signal indicates a data value associated with a particular state stored in the pair of memory cells.

With the use of the proposed memory architecture and operating scheme, the memory device can offer three states, including a zero state, for in-memory computing or ternary computing. The proposed memory architecture can realize a zero state without turning off each memory cell of the same row. When applied in a computing-in-memory (CIM) architecture, a deep neural network (DNN) or a convolution neural network (CNN), the proposed memory architecture not only can implement zero states in arbitrary pairs of memory cells, but also can achieve low power consumption.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating an exemplary memory device in accordance with some embodiments of the present disclosure.

FIG. 2 illustrates an implementation of circuitry associated with a pair of memory cells shown in FIG. 1 in accordance with some embodiments of the present disclosure.

FIG. 3 illustrates an implementation of the processing circuit shown in FIG. 2 in accordance with some embodiments of the present disclosure.

FIG. 4 is a diagram illustrating a truth table for the digital output shown in FIG. 3 in accordance with some embodiments of the present disclosure.

FIG. 5 illustrates another implementation of the processing circuit shown in FIG. 2 in accordance with some embodiments of the present disclosure.

FIG. 6 is a diagram illustrating a truth table for the digital output shown in FIG. 5 in accordance with some embodiments of the present disclosure.

FIG. 7 is a flow chart of an exemplary method for operating a memory device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

In order to reduce storage space and computational complexity, a binary neural arithmetic memory (BNAM) architecture is proposed to train the CNN with binary filter weights. For example, a filter weight of +1 corresponds to a current flowing in a positive direction, e.g. a charging current in a “+1” state. A filter weight of −1 corresponds to a current flowing in a negative direction, e.g. a discharging current in a “−1” state. However, the BNAM architecture would lead to high power consumption since there is a current flowing in either a positive or negative direction.

The present disclosure describes exemplary memory devices, each of which can include a pair of memory cells, such as twin cells coupled to a common wordline, to offer three or more states for ternary computing. The three states may include “+1”, “−1”, and “0” states. The bit pattern of two data bits stored in the pair of memory cells can stand for the three states. Each of the exemplary memory devices can be applied in, but is not limited to, a computing-in-memory (CIM) architecture, a deep neural network (DNN), and a convolution neural network (CNN). For example, the exemplary memory device can be used for implementing a ternary neural arithmetic memory architecture arranged to train a CNN with ternary filter weights. The “0” state corresponding to the filter weight of 0 can reduce power consumption in the CNN. The present disclosure further describes exemplary methods for operating memory devices. The proposed memory architecture and operating scheme can realize a zero state without turning off each memory cell of the same row. Further description is provided below.

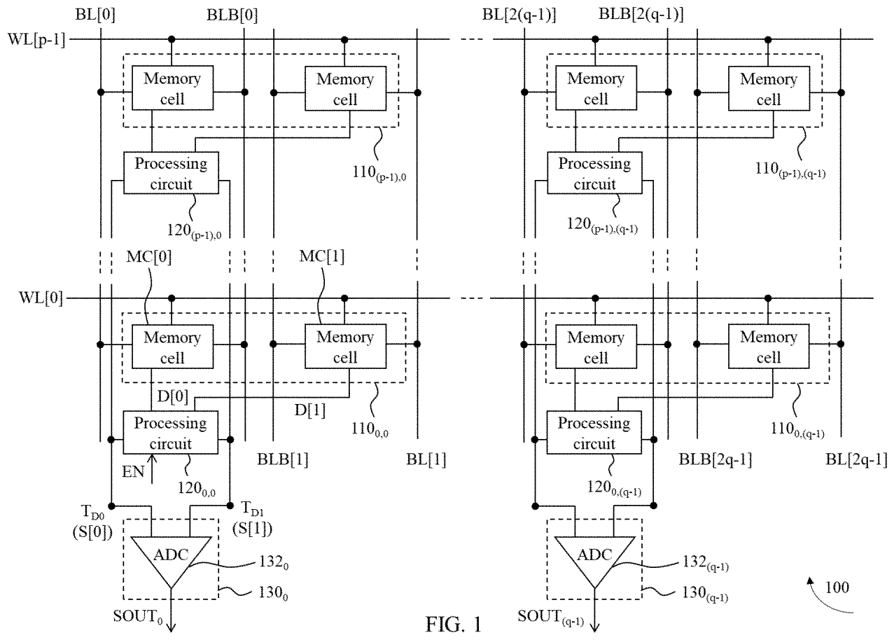

FIG. 1 is a diagram illustrating an exemplary memory device in accordance with some embodiments of the present disclosure. The memory device 100 can be used to implement at least a portion of an in-memory computing system, such as a ternary neural arithmetic memory capable of offering three states for ternary computing. The memory device 100 includes, but is not limited to, a plurality of pairs of memory cells 110_{0,0}-110_{(p-1),(q-1)}, a plurality of processing circuits 120_{0,0}-120_{(p-1),(q-0)}, and a plurality of signal generator circuits 130₀-130_{(q-1)}. Each of p and q is a positive integer greater than one.

In the present embodiment, memory cells included in the pairs of memory cells 110_{0,0}-110_{(p-1),(q-1)} are arranged in rows and columns. As a result, the pairs of memory cells 110_{0,0}-110_{(p-1),(q-1)} can be regarded as being arranged in p rows and q columns. In addition, the memory device 100 includes a plurality of wordlines WL[0]-WL[p−1] and a plurality of pairs of complementary bitlines. Each pair of the complementary bitlines includes bitlines BL[i] and BLB[i], where i=0, . . . , 2q−1. The memory cells arranged in the same row are coupled to a common wordline. The memory cells arranged in the same column are coupled to a common pair of complementary bitlines. Two memory cells in the same pair are coupled to a common wordline, and each of them is respectively coupled to the two bitlines in a pair of complementary bitlines. For example, the pair of memory cells 110_{0,0} includes memory cells MC[0] and MC[1], which are coupled to the wordline WL[0]. The memory cell MC[0] is further coupled to a pair of complementary bitlines, i.e. the bitlines BL[0] and BLB[0]. The memory cell MC[1] is further coupled to another pair of complementary bitlines, i.e. the bitlines BL[1] and BLB[1].

The processing circuits 120_{0,0}-120_{(p-1),(q-1)} are coupled to the pairs of memory cells 110_{0,0}-110_{(p-1),(q-1)}, respectively. Each processing circuit is configured to selectively adjust respective data signals at data terminals according to data stored in a corresponding pair of memory cells. For example, data stored in the pair of memory cells 110₀ includes data D[0] stored in the memory cell MC[0] and data D[1] stored in the memory cell MC[1]. The data D[0] and the data D[1] can jointly represent a plurality of states stored in the pair of memory cells 110₀. The processing circuit 120₀, coupled to the pair of memory cells 110₀, is configured to selectively adjust a data signal S[0] at a data terminal T_{D0} and a data signal S[1] at a data terminal T_{D1} according to the data D[0] and the data D[1].

By way of example but not limitation, when the data D[0] and the data D[1] jointly represent a first state, the processing circuit 120₀ can adjust one of respective signal levels of the data signals S[0] and S[1]. When the data D[0] and the data D[1] jointly represent a second state, the processing circuit 120₀ can adjust the other of the respective signal levels of the data signals S[0] and S[1]. When the data D[0] and the data D[1] jointly represent a third state, the processing circuit 120₀ does not adjust the respective signal levels of the data signals S[0] and S[1].

In the present embodiment, at least one processing circuit may receive an enable signal to selectively allow adjustment of associated data signals. For example, the processing circuit 120_{0,0} is configured to receive an enable signal EN to enable or disable adjustment of the data signals S[0] and S[1]. When the enable signal EN is asserted, the processing circuit 120_{0,0} is enabled to selectively adjust the data signals S[0] and S[1] according to the data D[0] and the data D[1]. When the enable signal EN is de-asserted, the processing circuit 120_{0,0} is inhibited to perform adjustment of the data signals S[0] and S[1].

The signal generator circuits 130₀-130_{(q-1)} are coupled to the processing circuits 120_{0,0}-120_{0,(q-1)} respectively. Each signal generator circuit is configured to generate an output signal according to a plurality of data signals, which are selectively adjusted by a corresponding processing circuit. The output signal can indicate a data value associated with a particular state stored in a pair of memory cells. For example, the signal generator circuit 130₀ is coupled to the processing circuit 120_{0,0} through the data terminals T_{D0} and T_{D1}. The signal generator circuit 130₀ is configured to generate an output signal SOUT₀ according to the data signals S[0] and S[1]. The output signal SOUT₀ can indicate a data value associated with a particular state stored in the pair of memory cells 110_{0,0}. Note that the data D[0] and the data D[1] can jointly represent three or more states stored in the pair of memory cells 110₀. The three or more states correspond to three or more data values, respectively. The output signal SOUT₀ can thus be applicable to ternary computing.

In the present embodiment, the signal generator circuits 130₀-130_{(q-1)} can be implemented using the ADCs 132₀-132_{(q-1)}, respectively. Each of the ADCs 132₀-132_{(q-1)} can be an N-bit ADC capable of producing at least three different digital values. N may be equal to or greater than two, and each digital value may correspond to a data value associated with a particular state. For example, the ADC 132₀ is configured to convert the data signals S[0] and S[1] into the output signal SOUT₀ such as a two-bit digital output (N=2). A difference between the data signals S[0] and S[1] can serve as an analog input of the ADC 132₀. The output signal SOUT₀ may have three distinct signal values, which correspond to three states stored in the pair of memory cells 110_{0,0}.

Further, at least one of the signal generator circuits 130₀-130_{(q-1)} can be coupled to a plurality of processing circuits, which are respectively coupled to a plurality of pairs of memory cells arranged in the same column. For example, the signal generator circuit 130₀ is coupled to each of the processing circuits 120_{0,0}-120_{(p-1),0} through the data terminals T_{D0} and T_{D1}. When one of the wordlines WL[0]-WL[p−1] is activated, the output signal SOUT₀ of the signal generator circuit 130₀ is indicative of a data value associated with a particular state stored in a pair of memory cells that are coupled to the activated wordline.

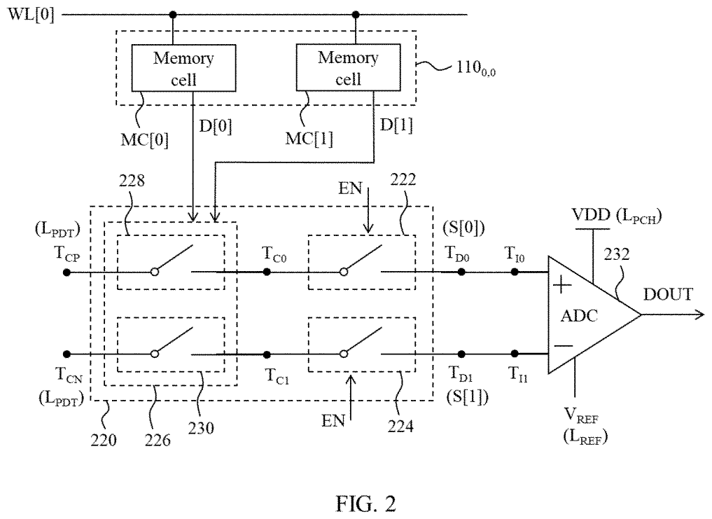

FIG. 2 illustrates an implementation of circuitry associated with the memory cells 110_{0,0} shown in FIG. 1 in accordance with some embodiments of the present disclosure. The circuitry includes a processing circuit 220 and an ADC 232, which represent embodiments of the processing circuit 120_{0,0} and the ADC 132₀ shown in FIG. 1 respectively. However, this is not meant to be limiting. Those skilled in the art will appreciate that the ADC 232 may be replaced with other types of signal generator circuits without departing from the scope of the present disclosure. In addition, each processing circuit shown in FIG. 1 can be implemented using the processing circuit 220.

The processing circuit 220 includes, but is not limited to, a switch 222, a switch 224, and a switch circuit 226. The switch 222 is configured to selectively couple the data terminal T_{D0} to the connection terminal T_{C0} according to the enable signal EN. When the data terminal T_{D0} is coupled to the connection terminal T_{C0}, the processing circuit 220 is allowed to adjust the data signal S[0] at the data terminal T_{D0}. Similarly, the switch 224 is configured to selectively couple the data terminal T_{D1} to the connection terminal T_{C1} according to the enable signal EN. When the data terminal T_{D1} is coupled to the connection terminal T_{C1}, the processing circuit 220 is allowed to adjust the data signal S[1] at the data terminal T_{D1}. In the present embodiment, the processing circuit 220 turns on each of the switches 222 and 224 when the enable signal EN is asserted. In this way, the processing circuit 220 can concurrently enable/disable the adjustment of the data signal S[0] and the adjustment of the data signal S[1].

The switch circuit 226, coupled to the memory cells MC[0] and MC[1], is configured to selectively couple one of connection terminals T_{C0} and T_{C1} to a predetermined level L_{PDT} according to the data D[0] and the data D[1]. In some embodiments, the switch circuit 226 is configured to selectively couple one of the connection terminals T_{C0} and T_{C1} to a connection terminal maintained at the predetermined level L_{PDT}. In some other embodiments, the switch circuit 226 is configured to selectively couple one of the connection terminals T_{C0} and T_{C1} to a connection terminal having a variable voltage level. Once the signal level at the connection terminal reaches the predetermined level L_{PDT}, one of the connection terminals T_{C0} and T_{C1} can be selectively coupled to the connection terminal according to the data D[0] and the data D[1].

In the present embodiment, the switch circuit 226 may include switches 228 and 230. The switch 228 is configured to selectively couple the connection terminal T_{C0} to the predetermined level L_{PDT}. The switch 230 is configured to selectively couple the connection terminal T_{C1} to the predetermined level L_{PDT}.

For example, each of connection terminals T_{CP} and T_{CN} can be maintained at the predetermined level L_{PDT}. The switch 228 can be controlled by the data D[0] to selectively couple the connection terminal T_{C0} to the connection terminal T_{CP}. The switch 230 can be controlled by the data D[1] to selectively couple the connection terminal T_{C1} to the connection terminal T_{CN}. As another example, each of connection terminals T_{CP} and T_{CN} may have a variable signal level. The signal level at the connection terminal T_{CP} may vary in response to the data D[1]. The switch 228 can selectively couple the connection terminal T_{C0} to the connection terminal T_{CP} according to the data D[0] when the signal level at the connection terminal T_{CP} reaches the predetermined level L_{PDT}. Similarly, the signal level at the connection terminal T_{CN} may vary in response to the data D[1]. The switch 230 can selectively couple the connection terminal T_{C1} to the connection terminal T_{CN} according to the data D[0] when the signal level at the connection terminal T_{CN} reaches the predetermined level L_{PDT}.

The ADC 232 has input terminals T_{I0} and T_{I1}, which are coupled to the data terminals T_{D0} and T_{D1} respectively. The ADC 232 is configured to convert respective data signals at the input terminals T_{I0} and T_{I1}, i.e. the data signals S[0] and S[1], into a digital output DOUT that indicates a data value associated with a particular state stored in the pair of memory cells 110_{0,0}. The digital output DOUT can serve as an embodiment of the output signal SOUT₀ shown in FIG. 1. In the example of FIG. 2, the ADC 232 can be configured to generate the digital output DOUT from a comparison with a reference voltage V_{REF}. The reference voltage V_{REF} can be, but is not limited to, half of a supply voltage VDD provided to the ADC 232.

In the present embodiment, each of the data signals S[0] and S[1] can be set to the same or substantially the same level before adjusted by the processing circuit 220. For example, the ADC 232 can be a precharged differential ADC, which is configured to precharge each of the input terminals T_{I0} and T_{I1} to the same or substantially the same signal level. After the precharging, the processing circuit 220 can selectively discharge one of the input terminals T_{I0} and T_{I1} according to the data D[0] and the data D[1]. For example, when the enable signal EN is asserted, the processing circuit 220 can perform switching operation according to the data D[0] and the data D[1]. The processing circuit 220 may couple one of the input terminals T_{I0} and T_{I1} to the predetermined level L_{PDT}, thereby discharging the one of the input terminals T_{I0} and T_{I1}. Alternatively, the processing circuit 220 may concurrently turn off the two discharge paths; one is the path between the input terminal T_{I0} and the connection terminal T_{C0}, and the other is the path between the input terminal T_{I1} and the connection terminal T_{C1}.

In operation, when the wordline WL[0] is activated, memory cells 110_{0,0}-110_{0,(q-1)} arranged in the same row are selected. The ADC 232 is operable to precharge each of the data terminals T_{D0} and T_{D1} to a precharge level L_{PCH} greater than the predetermined level L_{PDT}. The precharge level L_{PCH} can be, but is not limited to, a voltage level of the supply voltage VDD. After the precharging, the processing circuit 220 can selectively adjust the data signal S[0]/S[1] by discharging the input terminal T_{I0}/T_{I1}.

The processing circuit is enabled to operate when the enable signal EN is asserted. If the data D[0] is a logical high and the data D[1] is a logical low, the switches 222 and 228 are both turned on to discharge the input terminal T_{I0}. If the data D[0] is a logical low and the data D[1] is a logical high, the switches 224 and 230 are both turned on to discharge the input terminal T_{I1}. If the data D[0] and the data D[1] are same in logical level, neither of the switches 228 and 230 is turned on such that the processing circuit 220 would not discharge the input terminals T_{I0} and T_{I1}. In addition, when the enable signal EN is de-asserted, the switches 222 and 224 are both turned off such that the processing circuit 220 would not discharge the input terminals T_{I0} and T_{I1}.

Next, the ADC 232 can generate the digital output DOUT from a comparison with a reference level L_{REF} of the reference voltage V_{REF}. Different digital values of the digital output DOUT correspond to different states stored in the pair of memory cells 110_{0,0}. For example, when the signal level of data signal S[0] is less than the reference level L_{REF} and the signal level of data signal S[1] and the reference level L_{REF} have no substantial difference, the ADC 232 is operable to generate the digital output DOUT indicating a first data value for one of a positive state and a negative state. When the signal level of data signal S[1] is less than the reference level L_{REF} and the signal level of data signal S[0] and the reference level L_{REF} have no substantial difference, the ADC 232 is operable to generate the digital output DOUT indicating a second data value for the other of the positive state and the negative state. When each of the respective signal levels of the data signals S[0] and S[1] in comparison with the reference level L_{REF} leads to no substantial difference, the ADC 232 is operable to generate the digital output DOUT indicating a third data value for a zero state. The first, second and third data values can be used for in-memory computing.

With the use of the proposed memory architecture, a memory device such as the memory device 100 shown in FIG. 1 can be used for implementing a ternary neural arithmetic memory architecture. For example, different states stored in a pair of memory cells may include “+1”, “−1”, and “0” states for ternary computing. The memory device 100 can provide filter weights of +1, −1, and 0 for training a CNN. In addition, the memory device can realize a zero state without turning off each memory cell of the same row.

The structure and operation described above are provided for illustrative purposes, and are not intended to limit the scope of the present disclosure. In some embodiments, the ADC 232 can be configured to generate the digital output DOUT according to a difference in signal level between the data signals S[0] and S[1]. When the difference in signal level is less than a threshold level, the ADC 232 is operable to generate the digital output DOUT indicating a data value for one of a positive state and a negative state. The threshold level may be, but is not limited to, zero or the input offset voltage level of the ADC 232. When the difference in signal level is greater than the threshold level, the ADC 232 is operable to generate the digital output DOUT indicating a second data value for the other of the positive state and the negative state. When the difference in signal level and the threshold level are equal or substantially equal, the ADC 232 is operable to generate the digital output indicating a third data value for a zero state.

In some embodiments, at least one signal generator circuit shown in FIG. 1 can be configured to compare the data signal S[0] with the data signal S[1] to generate the output signal SOUT₀. For example, when a signal level of the data signal S[0] is less than a signal level of the data signal S[1], the signal generator circuit 130₀ is operable to generate the output signal SOUT₀ indicating a first data value for one of a positive state and a negative state. When the signal level of the data signal S[0] is greater than the signal level of the data signal S[1], the signal generator circuit 130₀ is operable to generate the output signal SOUT₀ indicating a second data value for the other of the positive state and the negative state. When the signal level of the data signal S[0] and the signal level of the data signal S[1] are substantially equal, the signal generator circuit 130₀ is operable to generate the output signal SOUT₀ indicating a third data value for a zero state

To facilitate understanding of the present disclosure, some embodiments of the processing circuit 220 shown in FIG. 2 are given below for further description of the proposed memory architecture. However, this is provided for illustrative purposes, and is not intended to limit the scope of the present disclosure. Furthermore, a pair of memory cells 110_{0,0} shown in FIG. 2 is implemented using a pair of static random access memory (SRAM) cells in the following embodiments. Those skilled in the art will appreciate that the proposed memory architecture can utilize other types of memory cells, each having at least one storage node, to offer at least three states for ternary computing without departing from the scope of the present disclosure.

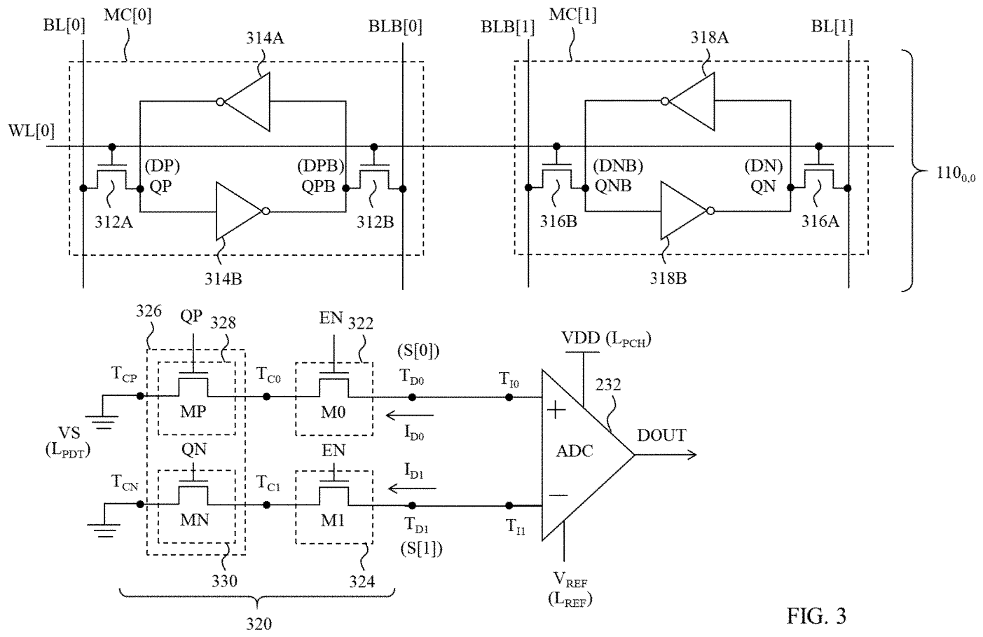

FIG. 3 illustrates an implementation of the processing circuit 220 shown in FIG. 2 in accordance with some embodiments of the present disclosure. In the present embodiment, each of the memory cells MC[0] and MC[1] can be implemented using a six-transistor (6T) SRAM cell. The memory cell MC[0] may include storage nodes QP and QPB, transistors 312A and 312B, and cross-coupled inverters 314A and 314B. The storage node QP can be arranged to store data DP. The storage node QPB can be arranged to store data DPB, which is a complement of the data DP. In other words, one of the storage nodes QP and QPB can serve as a complementary storage node of the other.

A control terminal of the transistor 312A is coupled to the wordline WL[0], a connection terminal of the transistor 312A is coupled to the bitline BL[0], and another connection terminal of the transistor 312A is coupled to the storage node QP. A control terminal of the transistor 312B is coupled to the wordline WL[0], a connection terminal of the transistor 312B is coupled to the bitline BLB[0], and another connection terminal of the transistor 312B is coupled to the storage node QPB. In addition, an input of the inverter 314A is coupled to the storage node QPB, and an output of the inverter 314A is coupled to the storage node QP. An input of the inverter 314B is coupled to the storage node QP, and an output of the inverter 314B is coupled to the storage node QPB. In the present embodiment, each of the inverters 314A and 314B can be implemented using a p-channel transistor and an n-channel transistor (not shown in FIG. 3).

Similarly, the memory cell MC[1] may include storage nodes QN and QNB, transistors 316A and 316B, and cross-coupled inverters 318A and 318B. The storage node QN can be arranged to store data DN. The storage node QNB can be arranged to store data DNB, which is a complement of the data DN. One of the storage nodes QN and QNB can serve as a complementary storage node of the other. The transistor 316A is configured to couple the bitline BL[1] to the storage node QN in response to activation of the wordline WL[0]. The transistor 316B is configured to couple the bitline BLB[1] to the storage node QNB in response to activation of the wordline WL[0]. An input of the inverter 318A is coupled to the storage node QN, and an output of the inverter 318A is coupled to the storage node QNB. An input of the inverter 318B is coupled to the storage node QNB, and an output of the inverter 318B is coupled to the storage node QN. In the present embodiment, each of the inverters 318A and 318B can be implemented using a p-channel transistor and an n-channel transistor (not shown in FIG. 3).

The processing circuit 320 is coupled to the storage node QP, the storage node QN, the input terminal T_{I0}, and the input terminal T_{I1}. The processing circuit 320 is configured to selectively adjust the data signals S[0] and S[1] according to the data DP, the data DN, and the enable signal EN. The data DP and data DN can serve as embodiments of the data D[0] and the data D[1] shown in FIG. 2, respectively. The processing circuit 320 includes switches 322 and 324, and a switch circuit 326. The switches 322 and 324 can represent embodiments of the switches 222 and 224 shown in FIG. 2, respectively. The switch circuit 326 can represent an embodiment of the switch circuit 226 shown in FIG. 2.

The switch 322 is controlled by the enable signal EN to selectively couple the input terminal T_{I0} to the connection terminal T_{C0}. The switch 324 is controlled by the enable signal EN to selectively couple the input terminal T_{I1} to the connection terminal T_{C1}. For example, the switch 322 is implemented using a transistor M0. A control terminal of the transistor M0 is coupled to the enable signal EN, a connection terminal of the transistor M0 is coupled to the input terminal T_{I0}, and another connection terminal of the transistor M0 is coupled to the connection terminal T_{C0}. Similarly, the switch 324 can be implemented using a transistor M1. A control terminal of the transistor M1 is coupled to the enable signal EN, a connection terminal of the transistor M1 is coupled to the input terminal T_{I1}, and another connection terminal of the transistor M1 is coupled to the connection terminal T_{C1}. According to the embodiments of the present disclosure, the transistors M0 and M1 are both turned on as the enable signal EN is asserted. This makes transistor M0 conductive between the terminals T_{I0} and T_{C0}, and makes transistor M1 conductive between the terminals T_{I1} and T_{C1} as well.

The switch circuit 326, coupled to the storage nodes QP and QN, is controlled by the data DP stored on the storage node QP and the data DN stored on the storage node QN. In the present embodiment, the switch circuit 326 includes switches 328 and 330, which can represent embodiments of the switches 228 and 230 shown in FIG. 2 respectively. The switch 328 is controlled by the data DP to selectively couple the connection terminal T_{C0} to a reference signal VS having the predetermined level L_{PDT}. The switch 330 is controlled by the data DN to selectively couple the connection terminal T_{C1} to the reference signal VS. The reference signal VS can be, but is not limited to, a ground voltage.

For example, the switch 328 is implemented using a transistor MP. A control terminal of the transistor MP is coupled to the storage node QP, a connection terminal of the transistor MP is coupled to the connection terminal T_{C0}, and another connection terminal of the transistor MP is coupled to the connection terminal T_{CP}. Similarly, the switch 330 can be implemented using a transistor MN. A control terminal of the transistor MN is coupled to the storage node QN, a connection terminal of the transistor MN is coupled to the connection terminal T_{C1}, and another connection terminal of the transistor MN is coupled to the connection terminal T_{CN}. Each of the connection terminals T_{CP} and T_{CN} is coupled to the reference signal VS and hence maintained at the predetermined level L_{PRE}.

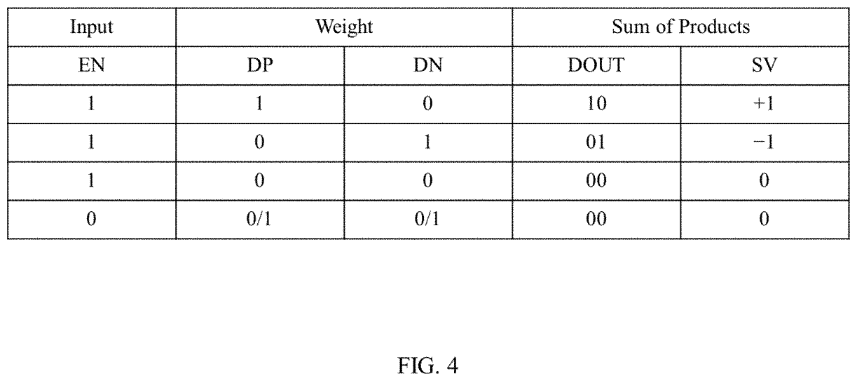

FIG. 4 is a diagram illustrating a truth table for the digital output DOUT shown in FIG. 3 in accordance with some embodiments of the present disclosure. Referring to FIG. 4 and also to FIG. 3, in some in-memory computing systems, the enable signal EN may serve as an input, the data DP and the data DN may serve as weights, and the digital output DOUT may serve as an associated sum of products. In addition, a data value SV is derived from a corresponding sum of products.

In operation, the ADC 232 can be configured to precharge each of the input terminals T_{I0} and T_{I1} to the precharge level L_{PCH}. After the precharging, the ADC 232 can generate the digital output DOUT from a comparison with the reference level L_{REF}. For example, the enable signal EN is asserted to turn on the transistors M0 and M1. When the data DP is a logical high and the data DN is a logical low, the transistor MP is turned on, and the transistor MN is turned off. There is a discharge current I_{D0} flowing from the input terminal T_{I0} through the transistor MP such that the signal level of the data signal S[0] decreases toward the predetermined level L_{PDT}. Meanwhile, the signal level of the data signal S[1] can be maintained at the precharge level L_{PCH}. The digital output DOUT, i.e. the resulting sum of products, is consequently encoded into a digital value “10” indicating a data value associated with a positive state stored in the pair of memory cell 110_{0,0}, i.e. the data value SV of +1.

Similarly, when the data DP is a logical low and the data DN is a logical high, the transistor MP is turned off, and the transistor MN is turned on. The signal level of the data signal S[0] is maintained at the precharge level L_{PCH}. There is a discharge current I_{D1} flowing from the input terminal T_{I1} through the transistor MN such that the signal level of the data signal S[1] decreases toward the predetermined level L_{PDT}. The digital output DOUT is consequently encoded into a digital value “01” indicating a data value associated with a negative state stored in the pair of memory cell 110_{0,0}, i.e. the data value SV of −1. In addition, when each of the data DP and the data DN is a logical low, the transistors MP and MN are both turned off. Respective signal levels of the data signals S[0] and S[1] are maintained at the precharge level L_{PCH}. Therefore, the digital output DOUT is encoded into a digital value “00” indicating a data value associated with a zero state stored in the pair of memory cell 110_{0,0}, i.e. the data value SV of 0.

Note that a zero state realized by the proposed memory architecture can reduce or eliminate power consumption since no or almost no discharge current is generated. The weighting algorithm including the use of zero states can save power on an in-memory computing system. Also, as a zero state can be realized by a pair of memory cells itself, any arbitrary pair of memory cells are able to offer the zero state within the proposed memory cell array. For example, when one pair of memory cells located in an activated row offers a positive or negative state, the proposed memory architecture can allow another pair of memory cells located in the same row to offer a zero state without deactivating the row. As another example, two pairs of memory cells arranged in a bitline direction can offer different data states including a zero state. Thus, when applied in a CIM architecture, a DNN or a CNN, the proposed memory architecture not only can implement zero states in arbitrary pairs of memory cells, but also can achieve low power consumption. Further, the proposed memory architecture can perform bit-scalable multiply-accumulate (MAC) operations in a highly parallel manner to mitigate errors in multi-bit computations.

Still referring to FIG. 3 and FIG. 4, the ADC 232 can output the digital output DOUT indicative of a zero state with the use of the enable signal EN. For example, when the enable signal EN is de-asserted to turn off the transistors M0 and M1, neither the input terminal T_{I0} nor the input terminal T_{I1} is discharged through the switch circuit 326. Respective signal levels of the data signals S[0] and S[1] can be maintained at the precharge level L_{PCH} regardless of the data DP/DN. The digital output DOUT is consequently encoded into a digital value “00” indicating a data value associated with a zero state stored in the pair of memory cell 110_{0,0}, i.e. the data value SV of 0. Note that the zero state can be realized without the use of discharge current, thus reducing power consumption.

The circuit structure and operation described above are provided for illustrative purposes, and are not intended to limit the scope of the present disclosure. In some embodiments, the memory cell MC[0]/MC[1] can be implemented using other types of SRAM cells such as 5-transistor, 8 or more transistors SRAM cells. In some embodiments, the memory cell MC[0]/MC[1] can be implemented using other types of memory cells, each having at least one storage node. In some embodiments, the transistor MP can be coupled to one of the storage nodes QPB and QNB, and thus controlled by one of the data DPB and the data DNB. The transistor MN can be coupled to the other of the storage nodes QPB and QNB, and thus controlled by the other of the data DPB and DNB. In other words, the data DPB and data DNB can serve as embodiments of the data D[0] and the data D[1] shown in FIG. 2. In some embodiments, the switches 322 and 324 may be optional. In some embodiments, at least one of the switches 322, 324, 328 and 330 can be implemented using a transmission gate or other types of switching elements. Such alternatives and associated modifications are contemplated as falling within the scope of the present disclosure.

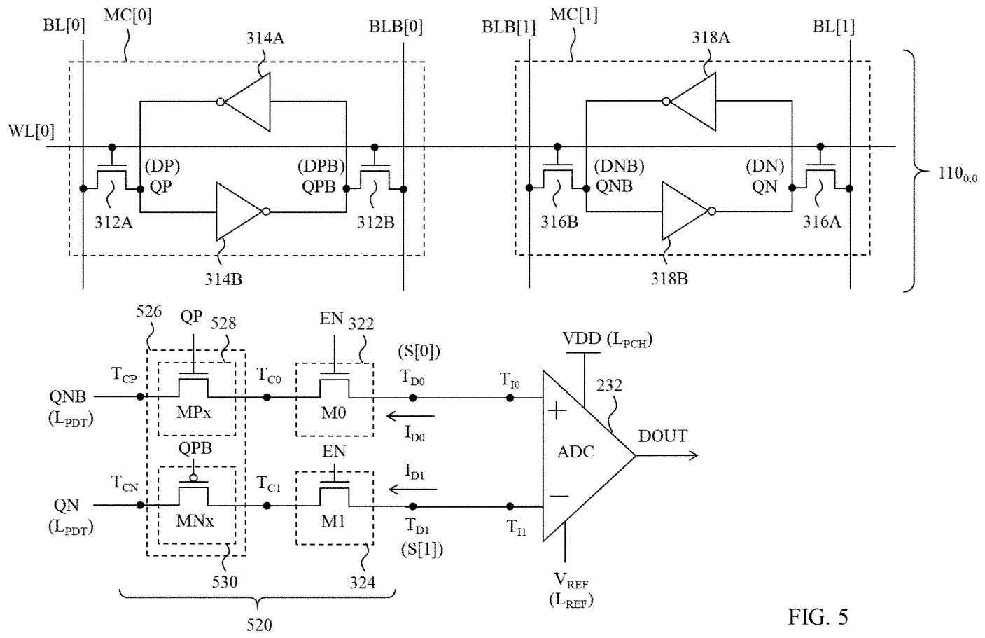

FIG. 5 illustrates another implementation of the processing circuit 220 shown in FIG. 2 in accordance with some embodiments of the present disclosure. The structure of the processing circuit 520 is similar/identical to that of the processing circuit 320 shown in FIG. 3 except for the switch circuit 526. The switch circuit 526 is coupled to the storage nodes QP, QPB, QN and QNB. The operation of the switch circuit 526 is controlled by the data DP, the data DPB, the data DN and the data DNB. In the present embodiment, the switch circuit 526 includes switches 528 and 530, which can represent embodiments of the switches 228 and 230 shown in FIG. 2 respectively.

The switch 528 is controlled by the data DP to selectively couple the connection terminal T_{C0} to the storage node QNB. When the data DP is a logical high and the data DPB is a logical low, the switch 528 is on and can couple the connection terminal T_{C0} to the storage node QNB. The signal level at the storage node QNB can serve as the predetermined level L_{PDT}. The switch 530 is controlled by the data DPB to selectively couple the connection terminal T_{C1} to the storage node QN. When the data DPB is a logical low and the data DN is a logical low, the switch 530 is on and can couple the connection terminal T_{C1} to the storage node QN, whose signal level can serve as the predetermined level L_{PDT}. In the arrangement of FIG. 5, the voltage level of the logical low is substantially equivalent to or close to the ground voltage.

For example, the switch 528 is implemented using a transistor MPx, which is an n-channel transistor. A control terminal of the transistor MPx is coupled to the storage node QP, a connection terminal of the transistor MPx is coupled to the connection terminal T_{C0}, and another connection terminal of the transistor MPx is coupled to the storage node QNB. The switch 530 can be implemented using a transistor MNx, which is a p-channel transistor. A control terminal of the transistor MNx is coupled to the storage node QPB, a connection terminal of the transistor MNx is coupled to the connection terminal T_{C1}, and another connection terminal of the transistor MN is coupled to the storage node QN.

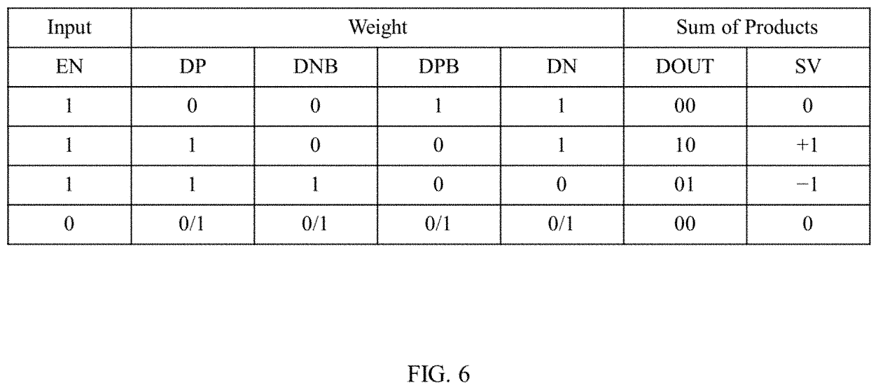

FIG. 6 is a diagram illustrating a truth table for the digital output DOUT shown in FIG. 5 in accordance with some embodiments of the present disclosure. Referring to FIG. 6 and also to FIG. 5, the data DP, the data DPB, the data DN and the data DNB may serve as weights for in-memory computing. In operation, after each of the input terminals T_{I0} and T_{I1} is precharged to the precharge level L_{PCH}, the enable signal EN can be asserted to turn on the transistors M0 and M1. When the data DP is a logical low and the data DN is a logical high, the data DPB is a logical high and the data DNB is a logical low. Each of the transistors MPx and MNx is turned off. Respective signal levels of the data signals S[0] and S[1] are maintained at the precharge level L_{PCH}. The digital output DOUT is encoded into a digital value “00” indicating a data value associated with a zero state stored in the pair of memory cell 110_{0,0}, i.e. the data value SV of 0. Note that the zero state can be realized without discharging a current, thus achieving low power consumption.

When each of the data DP and the data DN is a logical high, each of the data DPB and the data DNB is a logical low. The transistor MPx is turned on, and the transistor MNx is turned off. There is a discharge current I_{D0} flowing from the input terminal T_{I0} through the transistor MPx such that the signal level of the data signal S[0] decreases toward the signal level at the storage node QNB, i.e. the predetermined level L_{PDT}. Meanwhile, the signal level of the data signal S[1] can be maintained at the precharge level L_{PCH}. The digital output DOUT is consequently encoded into a digital value “10” indicating a data value associated with a positive state stored in the pair of memory cell 110_{0,0}, i.e. the data value SV of +1.

Moreover, when the data DP is a logical high and the data DN is a logical low, the data DPB is a logical low and the data DNB is a logical high. The transistor MPx is turned off, and the transistor MNx is turned on. The signal level of the data signal S[0] is maintained at the precharge level L_{PCH}. In the meantime, there is a discharge current I_{D1} flowing from the input terminal T_{I1} through the transistor MNx such that the signal level of the data signal S[1] decreases toward the signal level at the storage node QN, i.e. the predetermined level L_{PDT}. The digital output DOUT is encoded into a digital value “01” to indicate a data value associated with a negative state stored in the pair of memory cell 110_{0,0}, i.e. the data value SV of −1.

Note that the connection terminal T_{CP} of the transistor MPx is coupled to an internal node, i.e. the storage node QNB, rather than the true ground. Power consumption of the transistor MPx can be reduced accordingly. Similarly, the connection terminal T_{CN} of the transistor MNx is coupled to the storage node QN rather than the true ground. Power consumption of the transistor MNx can also be reduced accordingly.

Further, when the enable signal EN is de-asserted to turn off the transistors M0 and M1, neither the input terminal T_{I0} nor the input terminal T_{I1} is discharged through the switch circuit 526. Respective signal levels of the data signals S[0] and S[1] can be maintained at the precharge level L_{PCH} even though the transistor MPx/MNx is turned on. In this case, the digital output DOUT is encoded into a digital value “00” indicating a data value associated with a zero state stored in the pair of memory cell 110_{0,0}, i.e. the data value SV of 0. As those skilled in the art can appreciate the operation and alternatives of the processing circuit 520 shown in FIG. 5, similar description is not repeated for brevity.

Referring back to FIG. 2, in some embodiments, the processing circuit 220 may be regarded as including two transmission paths or two discharge paths. When one of the transmission paths is turned on and the other is turned off, the digital output DOUT of the ADC 232 can indicate that a data value associated with a particular state stored in the pair of memory cells 110_{0,0} is a positive value or a negative value. When each of the transmission paths is turned off, the digital output DOUT of the ADC 232 can indicate that a data value associated with a particular state stored in the pair of memory cells 110_{0,0} is a zero. For example, one of the transmission paths can be implemented using the switches 222 and 228, while the other of the transmission paths can be implemented using the switches 224 and 230. As another example, one of the transmission paths can be implemented using the switches 322 and 328 shown in FIG. 3, while the other of the transmission paths can be implemented using the switches 324 and 330 shown in FIG. 3. As still another example, one of the transmission paths can be implemented using the switches 322 and 528 shown in FIG. 5, while the other of the transmission paths can be implemented using the switches 324 and 530 shown in FIG. 5.

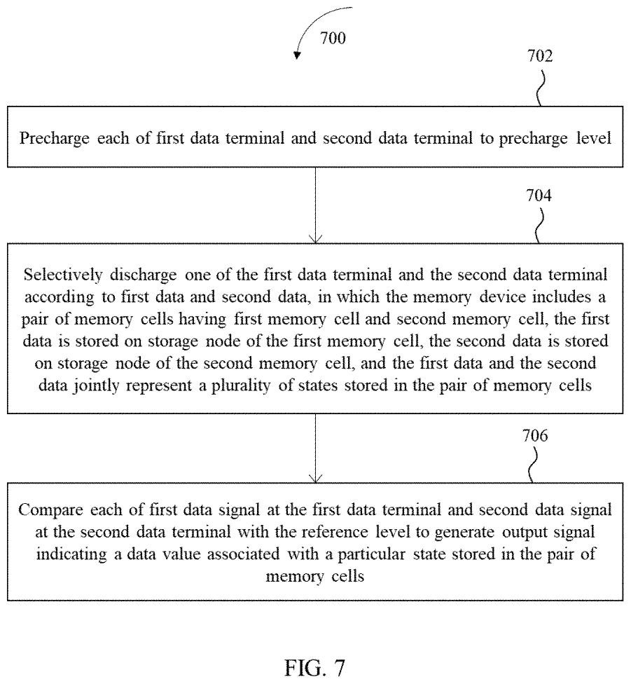

FIG. 7 is a flow chart of an exemplary method for operating a memory device in accordance with some embodiments of the present disclosure. For illustrative purposes, the method 700 is described below with reference to the memory cells 110_{0,0} and associated circuitry shown in FIG. 2. Note that the method 700 can be employed in the memory device 100 shown in FIG. 1, the memory cells 110_{0,0} shown in FIG. 3 or the memory cells 110_{0,0} shown in FIG. 5 without departing from the scope of the present disclosure. Additionally, in some embodiments, other operations in the method 700 can be performed. In some other embodiments, operations of the method 700 can vary.

At operation 702, each of a first data terminal and a second data terminal is precharged to a reference level. For example, the ADC 232 can precharge each of the data terminals T_{D0} and T_{D1} to the precharge level L_{PCH}, such as the voltage level of the supply voltage VDD.

At operation 704, one of the first data terminal and the second data terminal is selectively discharged according to first data and second data. The memory device includes a pair of memory cells having a first memory cell and a second memory cell. The first data is stored on a storage node of the first memory cell, and the second data is stored on a storage node of the second memory cell. The first data and the second data jointly represent a plurality of states stored in the pair of memory cells. For example, the processing circuit 220 is configured to selectively discharge one of the data terminals T_{D0} and T_{D1} according to the data D[0] stored in the memory cell MC[0] and the data D[1] stored in the memory cell MC[1]. The data D[0] and the data D[1] may be the data DP and the data DN shown in FIG. 3. Alternatively, the data D[0] and the data D[1] may be the data DPB and the data DNB shown in FIG. 3.

At operation 706, each of a first data signal at the first data terminal and a second data signal at the second data terminal is compared with the reference level to generate an output signal, which indicates a data value associated with a particular state stored in the pair of memory cells. For example, the ADC 232 can compare each of the data signals S[0] and S[1] with the reference level L_{REF} to generate the digital output DOUT, which can indicate a date value associated with a particular state stored in the pair of memory cells 110_{0,0}.

In some embodiments, at operation 704, the first data terminal is selectively coupled to a reference signal having a predetermined level L_{PDT} according to the first data. The predetermined level L_{PDT} is less than the reference level L_{REF}. In addition, the second data terminal is selectively coupled to the reference signal according to the second data. Accordingly, one of the first data terminal and the second data terminal can be selectively discharged. For example, the switch 228 can selectively couple the data terminal T_{D0} to the connection terminal T_{CP}, and the switch 230 can selectively couple the data terminal T_{D1} to the connection terminal T_{CN}. Each of the connection terminals T_{CP} and T_{CN} can be coupled to the reference signal having the predetermined level L_{PDT}, such as the reference signal VS shown in FIG. 3.

In some embodiments, the first memory cell may include a first complementary storage node for storing a complement of the first data, and the second memory cell may include a second complementary storage node for storing a complement of the second data. At operation 704, the first data terminal is selectively coupled to the second complementary storage node according to the first data. The second data terminal is selectively coupled to the second storage node according to the complement of the first data. For example, the switches 228 and 230 shown in FIG. 2 can be implemented using the switches 528 and 530 shown in FIG. 5, respectively. The connection terminals T_{CP} and T_{CN} shown in FIG. 2 can be coupled to the storage nodes QNB and QN shown in FIG. 5, respectively.

As those skilled in the art can appreciate the operation of the method 700 after reading the above paragraphs directed to FIG. 1 through FIG. 6, further description is omitted here for brevity.

With the use of the proposed memory architecture and operating scheme, the memory device can offer three states, including a zero state, for in-memory computing or ternary computing. The proposed memory architecture can realize a zero state without turning off each memory cell of the same row. When applied in a CIM architecture, a DNN or a CNN, the proposed memory architecture not only can implement zero states in arbitrary pairs of memory cells, but also can achieve low power consumption.

The foregoing outlined features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a pair of memory cells, having a first memory cell and a second memory cell;
an analog-to-digital converter (ADC), having a first input terminal and a second input terminal, configured to convert a first data signal at the first input terminal and a second data signal at the second input terminal to a digital output indicating a data value associated with a particular state stored in the pair of memory cells; and
a processing circuit, coupled to a storage node of the first memory cell, a storage node of the second memory cell, and the first and the second input terminals of the ADC, the processing circuit being configured to selectively adjust the first data signal and the second data signal according to first data stored on the storage node of the first memory cell and second data stored on the storage node of the second memory cell, wherein the first data and the second data jointly represent a plurality of states stored in the pair of memory cells.

2. The memory device of claim 1, wherein the ADC is further configured to precharge each of the first input terminal and the second input terminal to a precharge level; after the precharging, the processing circuit is configured to selectively discharge one of the first input terminal and the second input terminal according to the first data and the second data.

3. The memory device of claim 1, wherein the ADC generates the digital output from a comparison with a reference level; when a signal level of the first data signal is less than the reference level and a signal level of the second data signal and the reference level have no substantial difference, the ADC is operable to generate the digital output indicating a first data value for one of a positive state and a negative state; when the signal level of the second data signal is less than the reference level and the signal level of the first data signal and the reference level have no substantial difference, the ADC is operable to generate the digital output indicating a second data value for another of the positive state and the negative state; when each of the respective signal levels of the first data signal and the second data signal in comparison with the reference level leads to no substantial difference, the ADC is operable to generate the digital output indicating a third data value for a zero state.

4. The memory device of claim 1, wherein the ADC generates the digital output according to a difference in signal level between the first data signal and the second data signal; when the difference in signal level is less than a threshold level, the ADC is operable to generate the digital output indicating a first data value for one of a positive state and a negative state; when the difference in signal level is greater than the threshold level, the ADC is operable to generate the digital output indicating a second data value for another of the positive state and the negative state; when the difference in signal level and the threshold level are substantially equal, the ADC is operable to generate the digital output indicating a third data value for a zero state.

5. The memory device of claim 1, wherein the processing circuit comprises:
a first switch, configured to selectively couple the first input terminal of the ADC to a first connection terminal according to an enable signal;
a second switch, configured to selectively couple the second input terminal of the ADC to a second connection terminal according to the enable signal; and
a switch circuit, coupled to the storage node of the first memory cell and the storage node of the second memory cell, the switch circuit being configured to selectively couple one of the first connection terminal and the second connection terminal to a predetermined level according to the first data and the second data.

6. The memory device of claim 5, wherein:
when the first switch is turned on and the switch circuit is set to couple the first connection terminal to predetermined level, there is a discharge current flowing from the first input terminal of the ADC into the switch circuit; and
when the second switch is turned on and the switch circuit is set to couple the second connection terminal to predetermined level, there is a discharge current flowing from the second input terminal of the ADC into the switch circuit.

7. The memory device of claim 5, wherein the processing circuit turns on the first switch and the second switch when the enable signal is asserted.

8. The memory device of claim 5, wherein the switch circuit comprises:
a third switch, controlled by the first data (DP) to selectively couple the first connection terminal to a reference signal having the predetermined level; and
a fourth switch, controlled by the second data to selectively couple the second connection terminal to the reference signal.

9. The memory device of claim 5, wherein the switch circuit comprises:
a third switch, controlled by the first data (DP) to selectively couple the first connection terminal to a complementary storage node of the second memory cell, wherein the complementary storage node of the second memory cell is arranged for storing a complement of the second data; and
a fourth switch, controlled by a complement of the first data to selectively couple the second connection terminal to the storage node of the second memory cell;
when the first data is a logical high and the complement of the second data is a logical low, the third switch is set to couple the first connection terminal to the complementary storage node of the second memory cell, wherein a signal level at the complementary storage node of the second memory cell serves as the predetermined level;
when the complement of the first data is a logical low and the second data is a logical low, the fourth switch is set to couple the second connection terminal to the storage node of the second memory cell, wherein a signal level at the storage node of the second memory cell serves as the predetermined level.

10. The memory device of claim 1, wherein the first memory cell and the second memory cell are coupled to a common wordline of the memory device.

11. A memory device, comprising:
a pair of memory cells, having a first memory cell and a second memory cell;
a first switch, controlled by first data stored on a storage node of the first memory cell to selectively couple a first connection terminal to a reference signal;
a second switch, controlled by second data stored on a storage node of the second memory cell to selectively couple a second connection terminal to the reference signal;
a third switch, selectively made conductive between the first connection terminal and a first data terminal;
a fourth switch, selectively made conductive between the second connection terminal and a second data terminal; and
a signal generator circuit, coupled to the first data terminal and the second data terminal, the signal generator circuit being configured to generate an output signal according to a first data signal at the first data terminal and a second data signal at the second data terminal, wherein the first data and the second data jointly represent a plurality of states stored in the pair of memory cells, and the output signal indicates a data value associated with a particular state stored in the pair of memory cells.

12. The memory device of claim 11, wherein:
when each of the first switch and the third switch is turned on, there is a discharge current flowing from the first data terminal through the first switch; and
when each of the second switch and the fourth switch is turned on, there is a discharge current flowing from the second data terminal through the second switch.

13. The memory device of claim 11, wherein each of the third switch and the fourth switch is controlled by an enable signal; when the enable signal is asserted, each of the third switch and the fourth switch is turned on.

14. The memory device of claim 11, wherein the signal generator circuit is further configured to precharge each of the first data terminal and the second data terminal to a precharge level greater than a signal level of the reference signal.

15. The memory device of claim 11, wherein:
when a signal level of the first data signal is less than a signal level of the second data signal, the signal generator circuit is operable to generate the output signal indicating a first data value for one of a positive state and a negative state; when the signal level of the first data signal is greater than the signal level of the second data signal, the signal generator circuit is operable to generate the output signal indicating a second data value for another of the positive state and the negative state; and
when the signal level of the first data signal and the signal level of the second data signal are substantially equal, the signal generator circuit is operable to generate the output signal indicating a third data value for a zero state.

16. A memory device, comprising:
a pair of memory cells, having a first memory cell and a second memory cell, wherein a storage node of the first memory cell is arranged for storing first data, and a storage node of the second memory cell is arranged for storing second data;
a first switch, controlled by the first data to selectively couple a first connection terminal to a complementary storage node of the second memory cell, wherein the complementary storage node of the second memory cell is arranged for storing a complement of the second data;
a second switch, controlled by a complement of the first data to selectively couple a second connection terminal to the storage node of the second memory cell;
a third switch, selectively made conductive between the first connection terminal and a first data terminal;
a fourth switch, selectively made conductive between the second connection terminal and a second data terminal; and
a signal generator circuit, coupled to the first data terminal and the second data terminal, the signal generator circuit being configured to generate an output signal according to a first data signal at the first data terminal and a second data signal at the second data terminal, wherein the first data and the second data jointly represent a plurality of states stored in the pair of memory cells, and the output signal indicates a data value associated with a particular state stored in the pair of memory cells.

17. The memory device of claim 16, wherein:
when each of the first switch and the third switch is turned on, there is a discharge current flowing from the first data terminal through the first switch; and
when each of the second switch and the fourth switch is turned on, there is a discharge current flowing from the second data terminal through the second switch.

18. The memory device of claim 16, wherein each of the third switch and the fourth switch is controlled by an enable signal; when the enable signal is asserted, each of the third switch and the fourth switch is turned on.

19. The memory device of claim 16, wherein the signal generator circuit is further configured to precharge each of the first data terminal and the second data terminal to a precharge level;
when the first data is a logical high and the complement of the second data is a logical low, the first switch is set to couple the first connection terminal to the complementary storage node of the second memory cell, wherein a signal level at the complementary storage node of the second memory cell is less than the precharge level;
when the complement of the first data is a logical low and the second data is a logical low, the second switch is set to couple the second connection terminal to the storage node of the second memory cell, wherein a signal level at the storage node of the second memory cell is less than the precharge level.

20. The memory device of claim 16, wherein:
when a signal level of the first data signal is less than a signal level of the second data signal, the signal generator circuit is operable to generate the output signal indicating a first data value for one of a positive state and a negative state;
when the signal level of the first data signal is greater than the signal level of the second data signal, the signal generator circuit is operable to generate the output signal indicating a second data value for another of the positive state and the negative state; and
when the signal level of the first data signal and the signal level of the second data signal are substantially equal, the signal generator circuit is operable to generate the output signal indicating a third data value for a zero state (“0” state).
